(19) United States
(12) Patent Application Publication
(10) Pub. No.: US 2002/0096674 A1
(43) Pub. Date: Jul. 25, 2002

(54) Nucleation layer growth and lift-up of process for GaN wafer

(76) Inventors: Hak Dong Cho, Cupertino, CA (US); Seung Ho Park, Sunnyvale, CA (US); Sang Hyun Won, Cupertino, CA (US)

Correspondence Address: WILSON SONSINI GOODRICH & ROSATI, 650 PAGE MILL ROAD, PALO ALTO, CA, 943041050

(21) Appl. No.: 10/040,983

(22) Filed: Dec. 31, 2001

Related U.S. Application Data
(63) Continuation-in-part of application No. 09/836,780, filed on Apr. 16, 2001.
Application No. 09/836,780 is a division of application No. 09/478,954, filed on Jan. 7, 2000, now Pat. No. 6,372,041.
(60) Provisional application No. 60/115,177, filed on Jan. 8, 1999.

(51) Int. Cl. H01L 21/00; H01L 31/0328; H01L 33/00

(52) U.S. Cl. 257/22; 257/103; 257/189; 438/22; 438/48; 257/615; 438/933

(57) ABSTRACT

A method for growing GaN forms a group III alloy material in a processing chamber. A GaN nucleation layer is formed on the group III alloy in the processing chamber to provide a GaN substrate. A GaN structure is formed on the GaN substrate using a plurality of gas phase reactants in the processing chamber.

### CROSS-REFERENCE TO RELATED APPLICATIONS

This application is a continuation-in-part of U.S. patent application Ser. No. 09/836,780, filed Apr. 16, 2001, which is a divisional of U.S. patent application Ser. No. 09/478,954, filed Jan. 7, 2000, which claims the priority of U.S. Provisional Application No. 60/115,177, filed Jan. 8, 1999 all of which are incorporated herein.

### BACKGROUND OF THE INVENTION

1. Field of the Invention

This invention relates to the field of materials science and more particularly to the growth of semiconductor crystals.

2. Description of the Related Art

There is currently a demand in the computer and telecommunication industries for multicolor light emitting displays and improved data density in communication and recording. As a result of this demand, there is a strong desire for a semiconductor light emitting element capable of emitting light having shorter wavelengths ranging from a blue light wavelength to an ultraviolet wavelength.

The III-V nitrides, as a consequence of their electronic and optical properties and heterostructure character, are highly advantageous for use in the fabrication of a wide range of microelectronic structures. In addition to their wide band gaps, the III-V nitrides also have direct band gaps and are able to form alloys, which permit fabrication of well lattice-matched heterostructures. Consequently, devices made from the III-V nitrides can operate at high temperatures, with high power capabilities, and can efficiently emit light in the blue and ultraviolet regions of the electromagnetic spectrum. Devices fabricated from Ill-V nitrides have applications in full color displays, super-luminescent light-emitting diodes (LEDs), high density optical storage systems, and excitation sources for spectroscopic analysis applications. Furthermore, high temperature applications are found in automotive and aeronautical electronics.

Effective use of these advantages of the Ill-V nitrides, however, requires that such materials have device quality and structure accommodating abrupt heterostructure interfaces. As such, the Ill-V nitrides must be of single crystal character and substantially free of defects that are electrically or optically active.

Gallium nitride (or GaN) is a particularly advantageous Ill-V nitride and attention has recently focused on gallium nitride related compound semiconductors (In(x)Ga(y)Al(1−x−yN) (0≦x, y; x+y≦1) as materials for emitting blue light. This nitride species can be used to provide optically 15 efficient, high temperature, wide band gap heterostructure semiconductor systems having a convenient, closely matched heterostructure character. The direct transition type band structure of GaN permits highly efficient emission of light. Moreover, GaN emits light of shorter wavelength ranging from a blue light wavelength to an ultraviolet wavelength, due to a great band gap at room temperature of about 3.4 eV.

As no GaN substrates are currently found in the art, growth of these compounds must initially take place heteroepitaxially, for example GaN on silicon. However, heteroepitaxial growth has several technical drawbacks. In particular, two types of defects arise as a result of heteroepitaxial growth: (i) dislocation defects due to lattice mismatch; and (ii) dislocation defects due to different thermal coefficients between the substrate and the epitaxial layer.

The first type of defect includes dislocations due to the lattice mismatch between the GaN layer and the substrate. One typical substrate is sapphire. In the case where a gallium nitride related compound semiconductor crystal is grown on a sapphire substrate, a lattice mismatch up to approximately 16% is found between the GaN and the substrate. SiC is a closer lattice match, at an approximate lattice mismatch of 3%, but the mismatch is still quite large. Many other substrates have been used, but all of them have large lattice mismatches and result in a high density of defects in the grown layers.

The second type of defect includes dislocations generated during cool-down after growth. This defect is a result of different thermal coefficients of expansion of the substrate and epitaxial layer.

There are two typical methods in use for growing GaN compound semiconductor crystals. However, both suffer from deficiencies and/or limitations adversely affecting the quality of the GaN product. A first method uses a single crystalline sapphire as a substrate. A buffer layer is grown on the substrate for the purpose of relaxation of lattice mismatching between the sapphire substrate and the GaN compound semiconductor crystal. The buffer layer may be a AIN buffer layer or a GaAlN buffer layer. A GaN compound semiconductor crystal is grown in the buffer layer. While the buffer layers improve the crystallinity and surface morphology of the GaN compound semiconductor crystal, the crystal remains in a distorted state because of the lattice mismatch with the sapphire substrate. This distorted state results in dislocation defects described herein.

A second method attempts to reduce the lattice mismatch by providing a single crystal material as a substrate having a crystal structure and lattice constant that closely matches that of the GaN compound semiconductor crystal. One embodiment of this method uses aluminum garnet or gallium garnet as a substrate, but the lattice match using these compounds is not sufficient to provide much improvement. Another embodiment of this method uses substrate materials including MnO, ZnO, MgO, and CaO. While these oxides provide a better lattice match with the substrate, the oxides undergo thermal decomposition at the high temperatures required for the growth of the GaN compound semiconductor. Thermal decomposition of the substrate adversely affects the quality of the semiconductors obtained using this method.

As a result of these problems, typical GaN semiconductor devices suffer from poor device characteristics, short life span, and high cost. Full utilization of the properties of GaN semiconductors cannot be realized until a suitable substrate is available that allows for growth of high quality homoepitaxial layers. This requires development of processes for growth of the substrate material. For device applications, therefore, it would be highly advantageous to provide substrates of GaN, for epitaxial growth thereon of a GaN crystal layer.

There is a need for GaN semiconductor devices that have long life spans. There is a further need for GaN semiconductor devices that are low cost. There is yet a further need for GaN semiconductor devices that provide for growth of high quality homoepitaxial layers. There is another need for GaN bulk, single crystal semiconductor devices. There is a further need for GaN bulk, single crystal semiconductor devices suitable for use in the fabrication of optoelectronic devices.

### SUMMARY OF THE INVENTION

Accordingly, an object of the present invention is to provide GaN semiconductor devices, and their method of formation, that have long life spans.

Another object of the present invention is to provide GaN semiconductor devices, and their method of formation, that are low cost.

A further object of the present invention is to provide GaN semiconductor devices, and their method of formation, that are grown with high quality homoepitaxial layers.

Yet another object of the present invention is to provide bulk, single crystal semiconductor devices GaN semiconductor devices, and their method of formation.

Another object of the present invention is to provide GaN semiconductor devices, and their method of fabrication, that are suitable for use as components with optoelectronic devices.

Yet a further object of the present invention is to provide GaN semiconductor devices, and their method of fabrication, that do not use traditional seed substrates.

Still another object of the present invention is to provide GaN semiconductor devices, and their method of fabrication, that use group III alloy materials in place of traditional seed substrates.

These and other objects of the present invention are achieved in a method for growing GaN by forming a group III alloy material in a processing chamber. A GaN nucleation layer is formed on the group III alloy in the processing chamber to provide a GaN substrate. A GaN structure is formed on the GaN substrate using a plurality of gas phase reactants in the processing chamber.

In another embodiment of the present invention, a method for growing GaN forms a group III alloy material on a supporter that is positioned on a susceptor in a processing chamber. A GaN nucleation layer is then formed on the group III alloy in the processing chamber to provide a GaN substrate. A GaN structure is formed on the GaN substrate using a plurality of gas phase reactants in the processing chamber.

In another embodiment of the present invention, a nitride semiconductor device includes a GaN substrate formed by creating a group III alloy material on a supporter than is positioned on a susceptor. A GaN structure is formed on the GaN substrate.

### BRIEF DESCRIPTION OF THE FIGURES

FIG. 1 is a cross-section view of a susceptor and the formation of the GaN structure in one embodiment of the present invention.

FIG. 2 is a flow chart that illustrates one embodiment of a method of the present invention used for the growth of the GaN structure.

FIG. 3 illustrates the different layers and the lift-up in one embodiment of the present invention for the growth of a free standing bulk GaN wafer.

FIG. 4 is a flow chart of a illustrating one method of the present invention for growing freestanding, single bulk crystal GaN by homoepitaxy.

FIG. 5 is a diagram of a processing chamber in which the GaN semiconductor crystal of an embodiment is grown.

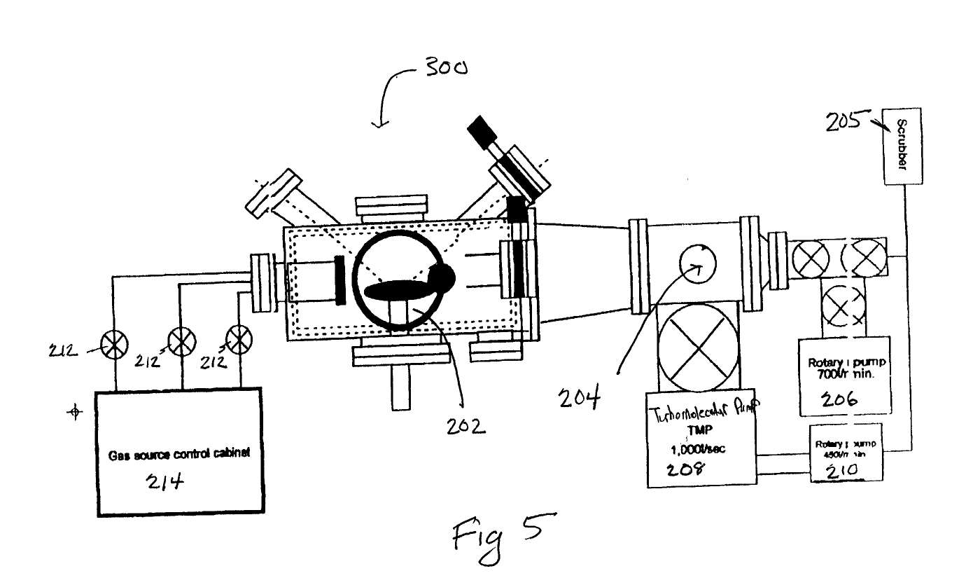

### DETAILED DESCRIPTION

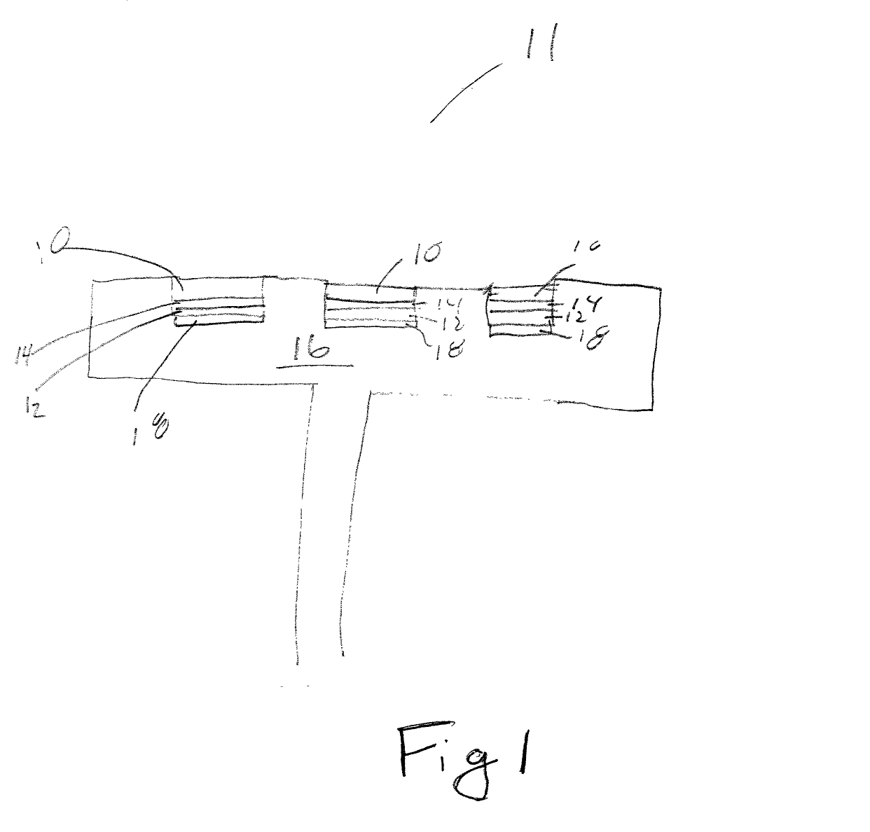

Referring to FIG. 1, one embodiment of the present invention provides a method for growing Gallium Nitride (GaN) to create a GaN structure, generally denoted as 10. In various embodiments, GaN structure 10 is grown at a rate in the range of 20 to 100 μm per hour.

One embodiment of the method forms a group III alloy material 12 in a processing chamber 11. Processing chamber 11 can be a variety of different sizes, designs and materials, including but not limited to ultra low oxygen stainless steel.

A GaN nucleation layer is formed on the group III alloy material 12 in processing chamber 11 to provide a GaN substrate 14. In one embodiment, GaN substrate 14 can have a thickness in a range of 10 to 70 Å. In one specific embodiment, GaN substrate 14 has ten monolayers and a thickness of 25 Å. GaN structure 10 is formed on GaN substrate 14 using a plurality of gas phase reactants in processing chamber 11. Additionally, the group III alloy material can be formed on a susceptor 16 in processing chamber 11. Suitable gas phase reactants include but are not limited to, nitrogen, hydrogen, ammonia, gallium, aluminum, indium, and the like.

In another embodiment of the present invention, the group III alloy material 12 is formed on a supporter 18 positioned on susceptor 16 in processing chamber 11. Supporter 18 can be made of a variety of different materials, including but not limited to Al₂O₃, SiC, Si, GaAs, InP, quartz and the like. Supporter 18 holds the group III-group alloy material 12 and can have diameter of at least 2 inches, and also have a thickness of 0.014 inches.

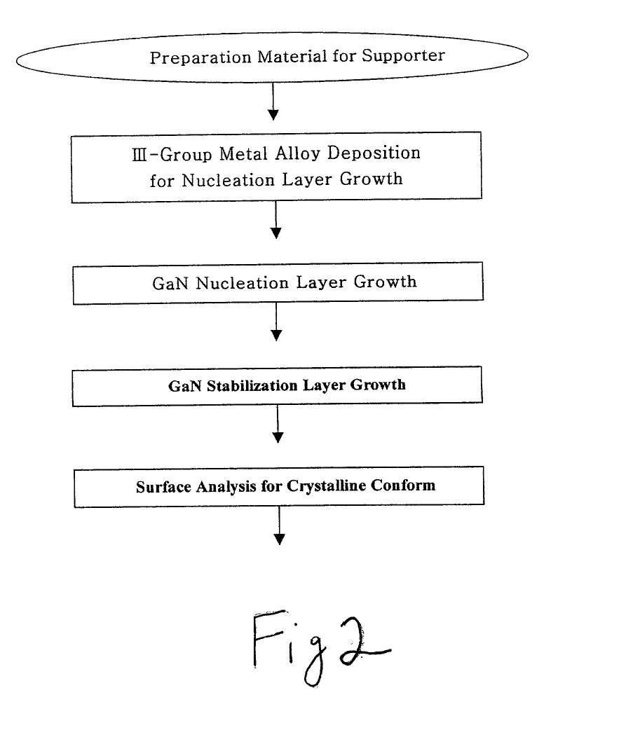

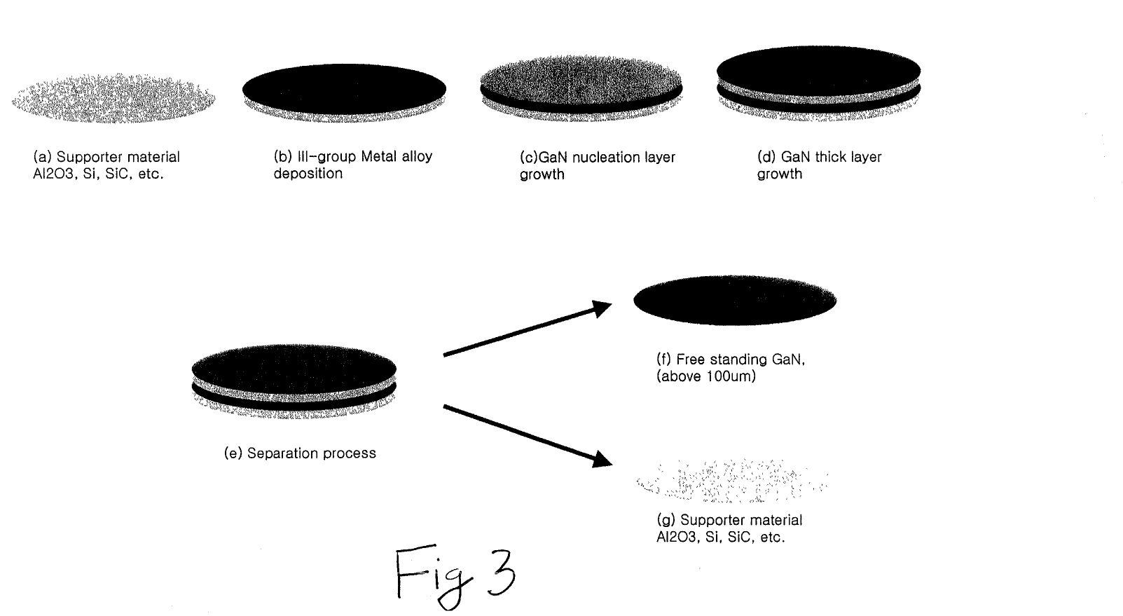

Susceptor 16 provides a holder of supporter 18. FIG. 2 is a flow chart that illustrates a method of the present invention with supporter 18 and susceptor 16. FIG. 3 illustrates nucleation layer growth and the lift-up process of one method of the present invention.

Susceptor 16 can be a PBN susceptor and hold more than three wafers In one specific embodiment of the present invention, susceptor 16 holds at least six wafers.

In various other embodiments, susceptor 16 is cleaned and then placed in processing chamber 11. One or both of processing chamber 11 and at least one heating element are then rotated. Thereafter, the environment of processing chamber 11 is initialized and stabilized.

The group III alloy material 12 provides a media for a lift-up, removal process of GaN structure 10 and also supports the GaN nucleation layer. The group III alloy material 12 can have a variety of different thickness and sizes, including but not limited to a range of 5 to 50,000 nm and 2 to 3 inches respectively. In one embodiment, the group III alloy material 12 is initially a solid state but transform into a liquid phase and evaporates at a certain temperature. This enhances the ability to lift off GaN structure 12. The GaN nucleation layer is the beginning layer for the thick growth of GaN structure 10.

GaN structure 10 can be, free standing GaN, single bulk GaN, a uniform structure GaN, a single crystal GaN and the like. In one embodiment, GaN structure 10 is a substrate with a size of at least 2 inches. In various embodiments, GaN structure 10 has a defect density of no more than 10⁷ cm⁻², no more than 10⁶ cm⁻², no more than 10⁵ cm⁻², and the like. In another embodiment, GaN substrate 14 is stabilized prior to the initiation of further growth of GaN structure 10.

GaN substrate 14 can include one or more mono-layers. The group III alloy material 12 can be a binary or a ternary alloy. Suitable group III alloy materials 12 include but are not limited to aluminum, gallium, indium and the like. When group III alloy material 12 is a binary alloy, preferred materials for the binary group III alloy material 12 include but are not limited to gallium and indium. For InGa, the ratio combinations of In are in the range of 10% to 50%, and 50% to 90% for Ga, to provide a total combination that equals 100%.

Suitable materials for ternary group III alloy material 12 include but are not limited to aluminum, indium, gallium, and the like. When group III alloy material 12 is AlInGa, the ratio combinations of Al are in the range of 10% to 50%, for I 10% to 50%, and for Ga 50% to 90%, to provide a total combination that equals 100%.

Examples of suitable supporter 18 materials include but are not limited to sapphire, silicon carbide, silicon, quartz. gallium arsenide, indium phosphate and the like. Preferably, supporter 18 is made of sapphire or silicon carbide.

GaN substrate 10 can be formed when the environment of processing chamber 11 is stabilized and controlled within a first set of environmental parameters. In one embodiment, the first set of environmental parameters includes a pressure selected from a range of 10⁻³ torr and 10⁻⁶ torr, a temperature selected from a range of 300° C. and 800° C. The selected temperature can be maintained within plus or minus 1° C.

Additionally, GaN structure 10 can also be formed when the environment of processing chamber 11 is stabilized and controlled within a second set of environmental parameters. In one embodiment, the second set of environmental parameters includes a pressure selected from a range of 10⁻³ torr and atmosphere, and a temperature in the range of 450° C. and 1250° C. In this embodiment, the selected temperature can be maintained within plus or minus 2° C.

The stabilization of GaN substrate 14 can be achieved by changing the environment of processing chamber 11 from the first set of environmental parameters to the second set of environmental parameters. It will be appreciated that the stabilization of GaN substrate from the first to the second set of environment parameters need not be the specific parameters listed in the preceding paragraph.

In one embodiment of the present invention, a method and the devices made by the method, are provided for the homoepitaxial growth of freestanding, Gallium Nitride (GaN) are provided. The GaN can be free standing GaN; single bulk GaN; a uniform structure GaN; single crystal GaN, and the like.

In one embodiment of the method of the present invention, GaN is nucleated in processing chamber 11 at a temperature, by way of illustration and without limitation, less than approximately 800° C. and a pressure substantially in the range of 10⁻³ torr to 10⁻⁶ torr. This nucleation phase results in the formation of the GaN nucleation layer which becomes GaN substrate 14 and can have a thickness of a few monolayers. GaN substrate 14 is then stabilized, and a single bulk crystal GaN is grown from gas phase reactants on GaN substrate 14, by way of illustration and without limitation, at a temperature that can be in the range of 450 to 1250° C. and a pressure that can be in the range of 10⁻³ torr to atmosphere.

In another embodiment of the present invention, the first step in growing GaN 10 without a typical base substrate includes growing GaN substrate 14. This can be achieved with the use of susceptor 16 that is rinsed with an organic solvent and than placed in processing chamber 11. Susceptor 16 can have a thickness, by way of illustration and without limitation, of approximately 3.5 to 4.5 millimeters and a diameter of approximately 5 inches. The parameters, including but not limited to pressure, temperature, rotational velocity, and the like, of processing chamber 30 environment are then set and stabilized.

In setting these parameters, the environment of processing chamber 30 can be controlled to maintain a selected pressure, by way of illustration and without limitation, of between 10⁻³ torr and 10⁻⁶ torr. In one embodiment, the selected pressure is 10⁻⁵ torr. In various embodiments, processing chamber 11 is heated to a selected temperature in the range of 300 to 800° C. and can be controlled to maintain the selected temperature within 1° C. Processing chamber can then be controllably rotated, by way of illustration and without limitation, at 700 RPM within 50 RPM.

A variety of different gases are introduced into processing chamber, including but not limited to, N₂, H₂, NH₃, Ga, Al, In, and the like with purities that can be as much as 99.99999%.

The surface of susceptor 16 can be cleaned by introducing N₂ gas into processing chamber 11. Gases can then be introduced into processing chamber, either simultaneously or non-simultaneously, for the nucleation phase. Flow rates of the gases can be adjusted for the nucleation phase. By way of illustration, and without limitation, the following flow rates can be used 5 to 10 cubic centimeters per minute for N₂; 0.1 to 0.25 liters per minute for NH₃; 0.001 to 0.002 liters per minute for Ga; 0.001 to 0.002 liters per minute for Al, and 0.001 to 0.002 liters per minute for In.

During the nucleation phase GaN substrate 14 can be grown, by way of illustration and without limitation, for a period of 10 minutes following introduction of the gas mixtures to processing chamber 11. By way of illustration, and without limitation, GaN substrate 14 can include 5 to 30 monolayers with a thickness substantially in the range of 10 to 70 Å plus or minus 10 Å. By way of illustration, and without limitation, the nominal nucleation layer can includes 10 monolayers with a thickness of approximately 25 Å.

The second step in growing a GaN semiconductor crystal without a typical base substrate can also include an interconnection process between the generation of GaN substrate 14 and the GaN layer growth. The interconnection process is used to stabilize GaN substrate 14 during a change in the environmental conditions of processing chamber 11.

During the interconnection process, by way of illustration, and without limitation, the temperature of processing chamber 30 environment can be changed at a constant rate of 3° C. per minute to a second selected temperature that is appropriate for growth of the GaN layer. This second selected temperature can be, by way of illustration and without limitation, in the range of 450 to 1250° C. When the second selected temperature, is reached, processing chamber 30 environment temperature can be controlled to maintain the second selected temperature plus or minus 2° C. The processing chamber environment can then be controlled, by way of illustration and without limitation, to a selected pressure between 10⁻³ torr and atmospheric pressure. Processing chamber 30 can continued to be controllably rotated at 700 RPM within 50 RPM. The gases can continue to be provided using the flow rates of the nucleation phase.

Measurements can be taken of GaN substrate 14 during its growth as well as the interconnection process. Specific measurements that can be made include but are not limited to, thickness and composition using elipsometric methods and instrumentation known in the art. Additionally, temperature measurement can by made using a pyrometer or other thermal instrumentation.

Following completion of the interconnection process, the gas flow rates into processing chamber 30 can be adjusted for the process of growing GaN on the nucleation layer, or the bulk phase. The following flow rates are used in GaN substrate 14. By way of illustration and without limitation the following gases can be introduced at the stated rates, N₂ at a flow rate of 2 to 3 liters per minute; H2 at a flow rate of 2 to 3 liters per minute; NH₃ at a flow rate of 1 to 2 liters per minute, Ga at a flow rate of 0.2 to 0.5 liters per minute, Al at a flow rate of 0.2 to 0.5 liters per minute, and In at a flow rate of 0.2 to 0.5 liters per minute.

The third step in growing GaN structure 10 includes growing a GaN layer on GaN substrate 14. By way of illustration and without limitation, a growth rate of 20 to 100 μm per hour can be achieved, with a nominal growth rate of 100 μm per hour. The resultant GaN structure 10 produced can have dimensions, by way of illustration and without limitation, of approximately 2 inches or more in diameter and a thickness of between 5 to 500 μm.

The lattice structure of the GaN layer grown on GaN substrate 14 can be a wurtzite structure. The orientation of the GaN layer can be (0001). By way of illustration and without limitation, the thickness of the GaN layer can be greater than 100 μm with a thickness uniformity of +/−5%, have a dislocation density of less than 10⁵ per square centimeter and have a full-width half-maximum intensity, as measured using ω-scan measurement, less than 100 arc seconds.

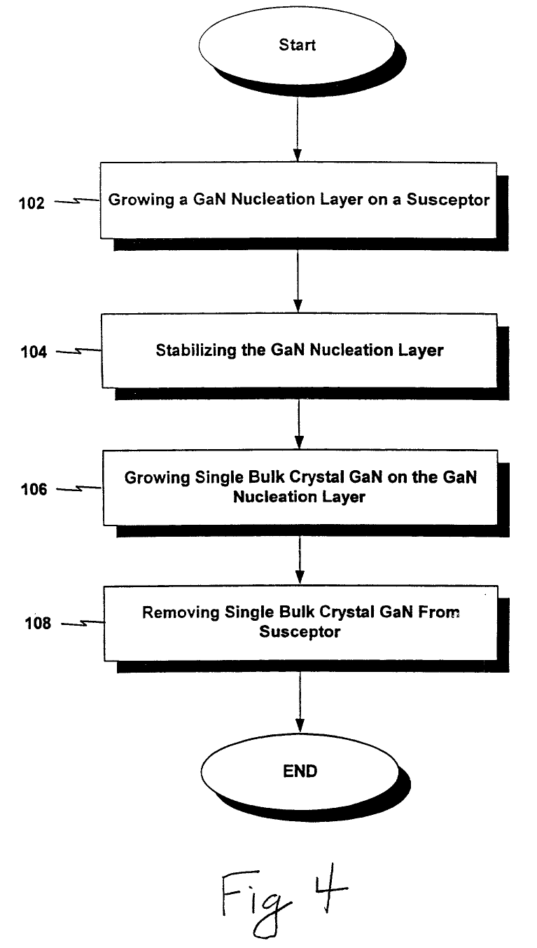

FIG. 4 is a flow chart that illustrates one specific method embodiment of the present invention for the formation of GaN structure 10 by homoepitaxy. Formation of GaN structure 10, as illustrated in FIG. 4, begins with nucleating GaN on susceptor 16 at step 102 in processing chamber 11 at a temperature that is less than approximately 800° C and a pressure about in the range of 10⁻³ torr to 10⁻⁶ torr. In various embodiments, the temperature can be in the range of 300 to 800° C., with a preferred range of 350 to 750° C. and specific embodiments of 400, 500 and 600° C. Similarly, the pressure can be in the range of 10⁻³ torr to 10⁻⁵ torr, with one preferred embodiment of 10⁻⁵ torr.

Nucleation step 102 results in the formation of the GaN nucleation layer which is then stabilized, at step 104. At step 106, GaN structure 10 is grown from gas phase reactants on the GaN nucleation layer in processing chamber 11. Step 106 can be achieved at a temperature substantially in the range of 450 to 1250° C. and a pressure substantially in the range of 10⁻³ torr to atmospheric pressure. GaN structure 10 is removed from susceptor 16 at step 108.

In one embodiment of the present invention, supporter 18 is placed on susceptor 16 and Group III alloy material 12 is then formed on supporter 18. This provides the mechanism of the lift-up process. The Group III alloy material 12 can undergo a phase transition, such as liquid to solid, solid to liquid, and/or vaporization, under certain temperature to assist in the lift off of GaN structure 10, along with GaN substrate 14.

With the methods of the present invention, the need for a base substrate of that is a different material, or a non-GaN material is eliminated. With the present invention, dislocation defect densities are several orders of magnitude less than other methods, and GaN structure 10 can have thicknesses greater than 100 μm.

Nitride semiconductor devices of the present invention include GaN substrate 14 formed by creating group III alloy material 12 on supporter 18 that is positioned on susceptor 16, followed by the growth of the GaN layers. In another embodiment, the nitride semiconductor devices of the present invention do not include the use of supporter 18. GaN 10 can be used as one component of a variety of different devices including but not limited to a, light-emitting diode, laser diode, HEMT, HFET, thyristor, HBT, rectifier, power switche, BJT, MOSFET, MESFET, SIS and the like.

The LED's and LD's can be included as components in a variety of different products including but not limited to, digital video disk devices, audio compact disk devices, computer CD-ROM drives, optical data storage devices, laser printers, rewriteable optical storage drives, barcode scanners, computer-to-plate digital printing presses, detectors, lasers for optical fiber communication, fill color electronic outdoor displays, flat panel displays and the like.

Additionally, with the present invention, three primary colors can be generated with GaN structure 10. White light sources, with adjustable mood coloring, can be created with GaN structure 10.

In one embodiment, GaN 10 is a wurtzite lattice structure. In various embodiments, the optical defect density of GaN 10 is less than 10⁸/cm², less than 10⁷/cm², less than 10⁶/cm², and the like.

In various embodiments, GaN 10 is doped with an impurity. The impurity can be a dopant, more particularly an n or an m-dopant. Suitable dopants include but are not limited to Si, Mg, and the like.

The dopant can be applied to GaN structure 10 prior to its incorporation in an optoelectronic device because the dopant can be applied directly to GaN substrate 14. One or both sides of GaN structure 10 can be doped.

A background donor concentration, for example (Nd—Na), of GaN structure 10 can be less than 10¹⁶ per cubic centimeter. In other embodiments, the background donor concentration can be less than 10¹⁵, 10¹⁴or 10¹³ per cubic centimeter.

FIG. 4 is a diagram that illustrates one embodiment of processing chamber 200 utilized to grow GaN 10. In one embodiment, processing chamber 200 is a double walled chamber having an inside diameter of approximately 14 inches. Processing chamber 200 can include a cooling system in the main body and an inlet gas body. Processing chamber 200 can include at least one port 202 for viewing, loading, and unloading, and at least one pumping port 204. In one embodiment, processing chamber 200 includes two or more pumping ports 204.

Processing chamber 200 can be made of ultra low oxygen stainless steel, including but not limited to grade 316L, 30316L or S31603 stainless steel, or other stainless steel known in the art, in order to reduce or eliminate introduction of impurities during the crystal growing process. The welds used in forming processing chamber 200 are performed so that oxygen contamination is prevented in the area of the welds. Furthermore, ultra low oxygen copper gaskets can be used in sealing processing chamber access ports 202. In one embodiment, the copper gaskets are used with 316L stainless steel Conflat flanges and flange components.

In various embodiments, processing chamber 200 can support pressures as low as 10⁻¹² torr, as well as pressures that not that low but are suitable for practicing the methods of the present invention. A staged vacuum system and scrubber 205 can be included, with rotary pumps 206 to generate and/or support pressures as low as approximately 10⁻³ torr. In one specific embodiment, rotary pumps 206 are rated for 700 liters per minute. Processing chamber 200 pressures can be between approximately 10⁻³ torr and 10⁻¹² torr with the use, for example, of at least one turbomolecular pump 208 and another rotary pump 210. The turbomolecular pump 208 can be rated for 1,000 liters per second. Rotary pump 210 can be rated for 450 liters per minute.

Processing chamber 200 can be coupled to a number of gas sources through a number of valves or regulators 212. The gas sources are contained in a gas source control cabinet 214.

Processing chamber 200 can have at least one heating unit that is capable of providing a processing chamber 200 environment with a temperature of at least 2500° C. In an embodiment, a processing chamber 200 temperature disparity is minimized using a three zone heating unit. Additionally, the heating unit can be rotatable independent of processing chamber 200 up to a speed of approximately 1500 RPM. The heating unit height can be raised or lowered through a range of approximately 0.50 inches to 0.75 inches. The heating elements of the heating unit can include graphite elements epitaxially coated with silicon carbide or pyro-boron nitride.

### EXAMPLE 1

GaN is grown by initially forming a group III alloy material in a pyroboron-nitride susceptor in a processing chamber. A GaN nucleation layer is then formed on the group III alloy in the processing chamber and provides a GaN substrate. The GaN structure is then formed on the GaN substrate using a plurality of gas phase reactants in the processing chamber. The phry-boron-nitride susceptor has a thickness of 3.5 to 4.5 mm, and is cleaned with an organic solvent.

The processing chamber is evacuated to a pressure of 10⁻⁹ torr. The temperature is then raised to 300 to 800° C. The susceptor is rotated relative to the processing chamber using a rotational velocity of about 700 rpm. Processing chamber conditions are stabilized for about ten minutes. The surface of the susceptor is cleaned by introducing 99.9999% pure N₂ gas at a pressure of 10⁻³ torr at a flow rate of 5 to 10 cubic centimeters per minute. NH₃ gas is provided at a flow rate of 0.1 to 0.25 liters per minute. Ga gas is provided at a flow rate of 0.001 to 0.002 liters per minute. Al gas is provided at a flow rate of 0.001 to 0.002 liters per minute. In gas is provided at a flow rate of 0.001 to 0.002 liters per minute. A GaN nucleation layer is then grown for a period of ten minutes.

The GaN nucleation layer has 5 to 30 monolayers with a total thickness of ten to 70 Å. Measurements of the nucleation layer are made using an elipsometer. During the stabilization step, the processing chamber is raised to a temperature of 450° C. at rate of 3 degrees per minute. The susceptor continued to be rotated relative to the processing chamber at a rate of 700 rpm. The gas flow rates into the processing chamber are adjusted for the bulk growth phase.

### EXAMPLE 2

Gallium nitride (GaN) was grown by initially forming a group III alloy material in a pyro -boron-nitride susceptor in a processing chamber. A GaN nucleation layer is then formed on the group III alloy in the processing chamber and provides a GaN substrate. The GaN structure is then formed on the GaN substrate using a plurality of gas phase reactants in the processing chamber. The phry-boron-nitride susceptor has a thickness of 3.5 to 4.5 mm, and is cleaned with an organic solvent.

The processing chamber is evacuated to a pressure of 10⁻⁹ torr. The temperature is then raised to 300 to 800° C. The susceptor is rotated relative to the processing chamber using a rotational velocity of about 700 rpm. Processing chamber conditions are stabilized for about ten minutes. The surface of the susceptor is cleaned by introducing 99.9999% pure N₂ gas at a pressure of 10⁻³ torr at a flow rate of 5 to 10 cubic centimeters per minute. NH₃ gas is provided at a flow rate of 0.1 to 0.25 liters per minute. Ga gas is provided at a flow rate of 0.001 to 0.002 liters per minute. Al gas is provided at a flow rate of 0.001 to 0.002 liters per minute. In gas is provided at a flow rate of 0.001 to 0.002 liters per minute. A GaN nucleation layer is then grown for a period of ten minutes.

The GaN nucleation layer has 5 to 30 monolayers with a total thickness of ten to 70 Å. Measurements of the nucleation layer are made using an elipsometer. During the stabilization step, the processing chamber is raised to a temperature of 450° C. at rate of 3 degrees per minute. The susceptor continued to be rotated relative to the processing chamber at a rate of 700 RPM. The gas flow rates into the processing chamber are adjusted for the bulk growth phase. A GaN structure is formed with a thickness of 290 μm and a diameter of 5 inches.

### EXAMPLE 3

Gallium nitride (GaN) was grown by initially forming a group III alloy material in a pyro-boron-nitride susceptor in a processing chamber. A GaN nucleation layer is then formed on the group III alloy in the processing chamber and provides a GaN substrate. The GaN structure is then formed on the GaN substrate using a plurality of gas phase reactants in the processing chamber. The phry-boron-nitride susceptor has a thickness of 3.5 to 4.5 mm, and is cleaned with an organic solvent.

The processing chamber is evacuated to a pressure of 10⁻⁹ torr. The temperature is then raised to 300 to 800° C. The susceptor is rotated relative to the processing chamber using a rotational velocity of about 700 rpm. Processing chamber conditions are stabilized for about ten minutes. The surface of the susceptor is cleaned by introducing 99.9999% pure N₂ gas at a pressure of 10⁻³ torr at a flow rate of 5 to 10 cubic centimeters per minute. NH₃ gas is provided at a flow rate of 0.1 to 0.25 liters per minute. Ga gas is provided at a flow rate of 0.001 to 0.002 liters per minute. In gas is provided at a flow rate of 0.001 to 0.002 liters per minute. A GaN nucleation layer is then grown for a period of ten minutes.

The GaN nucleation layer has 5 to 30 monolayers with a total thickness of ten to 70 Å. Measurements of the nucleation layer are made using an elipsometer. During the stabilization step, the processing chamber is raised to a temperature of 450° C. at rate of 3 degrees per minute. The susceptor continued to be rotated relative to the processing chamber at a rate of 700 rpm. The gas flow rates into the processing chamber are adjusted for the bulk growth phase.

### EXAMPLE 4

Gallium nitride (GaN) was grown by initially forming a group III alloy material in a pyro-boron-nitride susceptor in a processing chamber. A GaN nucleation layer is then formed on the group III alloy in the processing chamber and provides a GaN substrate. The GaN structure is then formed on the GaN substrate using a plurality of gas phase reactants in the processing chamber. The phry-boron-nitride susceptor has a thickness of 3.5 to 4.5 mm, and is cleaned with an organic solvent.

The processing chamber is evacuated to a pressure of 10⁻⁹ torr. The temperature is then raised to 300 to 800° C. The susceptor is rotated relative to the processing chamber using a rotational velocity of about 700 rpm. Processing chamber conditions are stabilized for about ten minutes. The surface of the susceptor is cleaned by introducing 99.9999% pure N₂ gas at a pressure of 10⁻³ torr at a flow rate of 5 to 10 cubic centimeters per minute. NH₃ gas is provided at a flow rate of 0.1 to 0.25 liters per minute. Ga gas is provided at a flow rate of 0.001 to 0.002 liters per minute. Al gas is provided at a flow rate of 0.001 to 0.002 liters per minute. In gas is provided at a flow rate of 0.001 to 0.002 liters per minute. A GaN nucleation layer is then grown for a period of ten minutes.

The GaN nucleation layer has 5 to 30 monolayers with a total thickness of 10 to 70 Å. Measurements of the nucleation layer are made using an elipsometer. During the stabilization step, the processing chamber is raised to a temperature of 450° C. at rate of 3 degrees per minute. The susceptor continued to be rotated relative to the processing chamber at a rate of 700 RPM. The gas flow rates into the processing chamber are adjusted for the bulk growth phase. A GaN structure is created with a thickness of 5 μm.

### EXAMPLE 5

Gallium nitride (GaN) was grown by initially forming a group III alloy material in a pyro-boron-nitride susceptor in a processing chamber. A GaN nucleation layer is then formed on the group III alloy in the processing chamber and provides a GaN substrate. The GaN structure is then formed on the GaN substrate using a plurality of gas phase reactants in the processing chamber. The phry-boron-nitride susceptor has a thickness of 3.5 to 4.5 mm, and is cleaned with an organic solvent.

The processing chamber is evacuated to a pressure of 10⁻⁹ torr. The temperature is then raised to 300 to 800 ° C. The susceptor is rotated relative to the processing chamber using a rotational velocity of about 700 rpm. Processing chamber conditions are stabilized for about ten minutes. The surface of the susceptor is cleaned by introducing 99.9999% pure N₂ gas at a pressure of 10⁻³ torr at a flow rate of 5 to 10 cubic centimeters per minute. NH₃ gas is provided at a flow rate of 0.1 to 0.25 liters per minute. Ga gas is provided at a flow rate of 0.001 to 0.002 liters per minute. Al gas is provided at a flow rate of 0.001 to 0.002 liters per minute. In gas is provided at a flow rate of 0.001 to 0.002 liters per minute. A GaN nucleation layer is then grown for a period of ten minutes.

The GaN nucleation layer has 5 to 30 monolayers with a total thickness of ten to 70 Å. Measurements of the nucleation layer are made using an elipsometer. During the stabilization step, the processing chamber is raised to a temperature of 450° C. at rate of 3 degrees per minute. The susceptor continued to be rotated relative to the processing chamber at a rate of 700 RPM. The gas flow rates into the processing chamber are adjusted for the bulk growth phase. A GaN structure is formed with a thickness of 500 μm. The foregoing description of a preferred embodiment of the invention has been presented for purposes of illustration and description. It is not intended to be exhaustive or to limit the invention to the precise forms disclosed. Obviously, many modifications and variations will be apparent to practitioners skilled in this art. It is intended that the scope of the invention be defined by the following claims and their equivalents.

What is claimed is:

1. A method for growing GaN, comprising:
forming a group III alloy material in a processing chamber;
forming a GaN nucleation layer on the group III alloy in the processing chamber to provide a GaN substrate; and
forming a GaN structure on the GaN substrate using a plurality of gas phase reactants in the processing chamber.

2. The method of claim 1, wherein the GaN substrate includes a plurality of mono-layers.

3. The method of claim 1, wherein the GaN structure includes a plurality of mono-layers.

4. The method of claim 1, wherein the group III alloy is a binary alloy.

5. The method of claim 4, wherein the binary alloy is InGa.

6. The method of claim 1, wherein the group III alloy is a ternary alloy.

7. The method of claim 6, wherein the ternary alloy is AlInGan.

8. The method of claim 1, wherein the group III alloy material is sized in the range of 2 to 3 inches.

9. The method of claim 1, wherein the GaN structure is sized in the range of 2 to 3 inches.

10. The method of claim 1, wherein the processing chamber is formed from ultra low oxygen stainless steel.

11. The method of claim 1, wherein the group III alloy material is formed on a susceptor in the processing chamber.

12. The method of claim 11, further comprising:
cleaning the susceptor;
setting the susceptor in the processing chamber;
rotating at least one of the processing chamber and at least one heating element; and
initializing and stabilizing an environment of the processing chamber.

13. The method of claim 1, wherein the GaN structure is free standing GaN.

14. The method of claim 1, wherein the GaN structure is single bulk GaN.

15. The method of claim 1, wherein the GaN structure is a uniform structure GaN.

16. The method of claim 1, wherein the GaN structure is single crystal GaN.

17. The method of claim 1, wherein the GaN structure is a substrate that is larger than 2 inches.

18. The method of claim 1, wherein the GaN structure is a substrate with a diameter of at least 2 inches.

19. The method of claim 1, wherein the GaN structure has a defect density of no more than 10⁷ cm⁻².

20. The method of claim 1, wherein the GaN structure has a defect density of no more than 10⁵ cm⁻².

21. The method of claim 1, wherein forming the GaN substrate is performed when the environment of the processing chamber is stabilized and controlled within a first set of environmental parameters.

22. The method of claim 21, wherein the first set of environmental parameters includes a pressure selected from a range of 10⁻³ torr and 10⁻⁶ torr and a temperature selected from a range of 300 and 800° C., wherein the selected temperature is maintained within plus or minus 1° C.

23. The method of claim 21, wherein forming the GaN structure is performed when the environment of the processing chamber is stabilized and controlled within a second set of environmental parameters.

24. The method of claim 21, wherein the second set of environmental parameters includes a pressure selected from a range of 10⁻³ torr and atmosphere and a temperature selected from a range of 450 and 1250° C., wherein the selected temperature is maintained within plus or minus 2 C.

25. The method of claim 2, farther comprising:
stabilizing the GaN substrate.

26. The method of claim 25, wherein stabilizing the GaN substrate includes changing the environment of the processing chamber from a first set of environmental parameters to a second set of environmental parameters.

27. The method of claim 1, wherein the plurality of gas phase reactants comprise gases are selected from nitrogen, hydrogen, ammonia, gallium, aluminum, and indium.

28. The method of claim 11, wherein the susceptor is a PBN susceptor.

29. The method of claim 11, wherein the susceptor holds more than three wafers.

30. The method of claim 11, wherein the susceptor holds at least six wafers.

31. The method of claim 1, wherein the GaN substrate has a thickness in a range of 10 to 70 Å.

32. The method of claim 1, wherein the GaN structure is grown at a rate in the range of 20 and 100 μm per hour.

33. A method for growing GaN, comprising:
forming a group III alloy material on a supporter positioned on a susceptor in a processing chamber;
forming a GaN nucleation layer on the group III alloy in the processing chamber to provide a GaN substrate; and
forming a GaN structure on the GaN substrate using a plurality of gas phase reactants in the processing chamber.

34. The method of claim 33, wherein the supporter is selected from sapphire, silicon carbide, silicon and quartz.

35. The method of claim 33, wherein the supporter is sized in the range of 2 to 3 inches.

36. The method of claim 33, wherein the GaN substrate includes a plurality of mono-layers.

37. The method of claim 33, wherein the GaN structure includes a plurality of mono-layers.

38. The method of claim 33, wherein the group III alloy is a binary alloy.

39. The method of claim 104, wherein the binary alloy is selected from indium and gallium.

40. The method of claim 33, wherein the group III alloy is a ternary alloy.

41. The method of claim 106, wherein the ternary alloy is selected from aluminum, indium and gallium.

42. The method of claim 33, wherein the group III alloy material is sized in the range of 2 to 3 inches.

43. The method of claim 33, wherein the GaN structure is sized in the range of 2 to 3 inches.

44. The method of claim 33, wherein the processing chamber is formed from ultra low oxygen stainless steel.

45. The method of claim 33, further comprising:
cleaning the susceptor;
setting the susceptor in the processing chamber;
rotating at least one of the processing chamber and at least one heating element; and
initializing and stabilizing an environment of the processing chamber.

46. The method of claim 33, wherein the GaN structure is free standing GaN.

47. The method of claim 33, wherein the GaN structure is single bulk GaN.

48. The method of claim 33, wherein the GaN structure is a uniform structure GaN.

49. The method of claim 33, wherein the GaN structure is single crystal GaN.

50. The method of claim 33, wherein the GaN structure has a diameter larger than 2 inches.

51. The method of claim 33, wherein the GaN structure has a defect density of no more than 10⁷ cm⁻².

52. The method of claim 33, wherein the GaN structure has a defect density of no more than 10⁵ cm⁻².

53. The method of claim 33, wherein forming the GaN substrate is performed when the environment of the processing chamber is stabilized and controlled within a first set of environmental parameters.

54. The method of claim 53, wherein the first set of environmental parameters includes a pressure selected from a range of 10⁻³ torr and 10⁻⁶ torr and a temperature selected from a range of 300 and 800° C., wherein the selected temperature is maintained within plus or minus 1° C.

55. The method of claim 53, wherein forming the GaN structure is performed when the environment of the processing chamber is stabilized and controlled within a second set of environmental parameters.

56. The method of claim 55, wherein the second set of environmental parameters includes a pressure selected from a range of 10⁻³ torr and atmosphere and a temperature selected from a range of 450 and 1250° C., wherein the selected temperature is maintained within plus or minus 2° C.

57. The method of claim 33, further comprising:
stabilizing the GaN substrate.

58. The method of claim 57, wherein stabilizing the GaN substrate includes changing the environment of the processing chamber from a first set of environmental parameters to a second set of environmental parameters.

59. The method of claim 33, wherein the plurality of gas phase reactants comprise gases are selected from nitrogen, hydrogen, ammonia, gallium, aluminum, and indium.

60. The method of claim 33, wherein the susceptor is a PBN susceptor.

61. The method of claim 33, wherein the susceptor holds more than three wafers.

62. The method of claim 33, wherein the susceptor holds at least six wafers.

63. The method of claim 33, wherein the GaN substrate has a thickness in a range of 10 to 70 Å.

64. The method of claim 33, wherein the GaN structure is grown at a rate in the range of 20 and 100 μm per hour.

65. A nitride semiconductor device, comprising:
a GaN substrate formed by creating a group III alloy material on a supporter than is positioned on a susceptor; and
a GaN structure formed on the GaN substrate.

66. The device of claim 65, wherein the group III alloy material is made of a binary alloy.

67. The device of claim 66, wherein the binary alloy is selected from indium and gallium.

68. The device of claim 65, wherein the group III alloy material is made of a ternary alloy.

69. The device of claim 68, wherein the ternary alloy is selected from aluminum, indium and gallium.

70. The device of claim 65, wherein the nitride semiconductor device has a thickness in the range of 5 to 500 μm.

71. The device of claim 65, wherein the supporter is selected from sapphire, silicon carbide, silicon and quartz.

72. The device of claim 65, wherein the supporter has a size in the range of 2 to 3 inches.

73. The device of claim 65, wherein the nitride semiconductor device has a thickness of at least 100 μm and a diameter of at least 2 inches.

74. The device of claim 65, wherein the GaN structure is free standing GaN.

75. The device of claim 65, wherein the GaN structure is single bulk GaN.

76. The device of claim 65, wherein the GaN structure is a uniform structure GaN.

77. The device of claim 65, wherein the GaN structure is single crystal GaN.

78. The device of claim 65, wherein the substrate includes 5 to 30 monolayers and a thickness dimension in a range of 10 to 70 Å, and the GaN structure is grown at a rate between 20 and 100 μm per hour.

79. The device of claim 65, wherein the nitride semiconductor device is used in at least a, light-emitting diode, laser diode, HEMT, HFET, thyristors, HBT, rectifier, power switches, BJT, MOSFET, MESFET and SIS.

80. The device of claim 65, wherein at least one of the GaN substrate structure is a wurtzite lattice structure.

81. The device of claim 65, wherein one of a defect density, a dislocation defect density, or an optical defect density of the nitride semiconductor device is less than 10⁸/cm².

82. The device of claim 65, wherein one of a defect density, a dislocation defect density, or an optical defect density of the nitride semiconductor device is less than 10⁷/cm².

83. The device of claim 65, wherein one of a defect density, a dislocation defect density, or an optical defect density of the nitride semiconductor device is less than 10⁶/cm².

84. The device of claim 65, further comprising an impurity.

85. The device of claim 84, wherein the GaN structure is doped with the impurity.

86. The device of claim 84, wherein the impurity is a dopant.

87. The device of claim 84, wherein the doping material is an n-doping material.

88. The device of claim 84, wherein the doping material is a Si impurity.

89. The device of claim 84, wherein the doping material is a p-doping material.

90. The device of claim 86, wherein the doping material is a Mg impurity.
